(19) United States
(12) Patent Application Publication
(10) Pub. No.: US 2025/0191910 A1
(43) Pub. Date: Jun. 12, 2025

(54) SUBSTRATE PROCESSING METHOD AND SUBSTRATE PROCESSING SYSTEM

(71) Applicant: Tokyo Electron Limited, Tokyo (JP)

(72) Inventors: Ryuichi ASAKO, Nirasaki City, Yamanashi (JP); Mitsuaki IWASHITA, Nirasaki City, Yamanashi (JP); Hirokazu UEDA, Osaka City, Osaka (JP)

(21) Appl. No.: 18/844,277

(22) PCT Filed: Feb. 24, 2023
(86) PCT No.: PCT/JP2023/006871

§ 371 Date: Sep. 5, 2024

(30) Foreign Application Priority Data
Mar. 9, 2022 (JP) 2022-036544

(51) Int. Cl. H01L 21/02; H01L 21/311; H01L 21/67

(52) U.S. Cl. CPC H01L 21/02282; H01L 21/31133; H01L 21/6715

(57) ABSTRACT

A substrate processing method according to one embodiment of the present disclosure includes preparing a substrate having a target film exposed on a surface of the substrate, forming a liquid film on a surface of the target film by supplying an ionic liquid containing an oxoacid structure having 6 or more carbon atoms to the surface of the substrate at a first temperature, forming a solid film by cooling the substrate to a second temperature lower than the first temperature to solidify the liquid film, and removing the solid film by supplying a polar solvent to the substrate.

### TECHNICAL FIELD

The present disclosure relates to a substrate processing method and a substrate processing system.

### BACKGROUND

A technique is known in which a liquid material containing an ionic liquid is applied onto a substrate to form a protective film (e.g., see Patent Document 1).

### PRIOR ART DOCUMENTS

### Patent Document

Patent Document 1: International Publication No. 2021/220883

The present disclosure provides a technique capable of forming a protective film that exhibits a high barrier property against an oxidizing gas and is easily removable.

### SUMMARY

According to one embodiment of the present disclosure, there is provided a substrate processing method including preparing a substrate having a target film exposed on a surface of the substrate, forming a liquid film on a surface of the target film by supplying an ionic liquid containing an oxoacid structure having 6 or more carbon atoms to the surface of the substrate at a first temperature, forming a solid film by cooling the substrate to a second temperature lower than the first temperature to solidify the liquid film, and removing the solid film by supplying a polar solvent to the substrate.

According to the present disclosure, it is possible to form a protective film that exhibits a high barrier property against an oxidizing gas and is easily removable.

### BRIEF DESCRIPTION OF DRAWINGS

FIG. 1 is a flowchart illustrating a substrate processing method according to an embodiment.

FIG. 2A is a cross-sectional view illustrating the substrate processing method according to the embodiment.

FIG. 2B is a cross-sectional view illustrating the substrate processing method according to the embodiment.

FIG. 2C is a cross-sectional view illustrating the substrate processing method according to the embodiment.

FIG. 2D is a cross-sectional view illustrating the substrate processing method according to the embodiment.

FIG. 3 is a schematic diagram illustrating an example of a coating device.

FIG. 4 is a schematic diagram illustrating one example of a substrate processing system.

FIG. 5 is a schematic diagram illustrating another example of a substrate processing system.

FIG. 6 is a diagram illustrating an example of a process including the substrate processing method.

FIG. 7 is a cross-sectional view (1) illustrating the example of the process including the substrate processing method.

FIG. 8 is a cross-sectional view (2) illustrating the example of the process including the substrate processing method.

FIG. 9 is a cross-sectional view (3) illustrating the example of the process including the substrate processing method.

FIG. 10 is a cross-sectional view (4) illustrating the example of the process including the substrate processing method.

FIG. 11 is a cross-sectional view (5) illustrating the example of the process including the substrate processing method.

FIG. 12 is a cross-sectional view (6) illustrating the example of the process including the substrate processing method.

FIG. 13 is a cross-sectional view (7) illustrating the example of the process including the substrate processing method.

FIG. 14 is a cross-sectional view (8) illustrating the example of the process including the substrate processing method.

FIG. 15 is a cross-sectional view (9) illustrating the example of the process including the substrate processing method.

FIG. 16A is a cross-sectional view illustrating a method of producing a sample for solid film evaluation.

FIG. 16B is a cross-sectional view illustrating the method of producing a sample for solid film evaluation.

FIG. 16C is a cross-sectional view illustrating the method of producing a sample for solid film evaluation.

FIG. 16D is a cross-sectional view illustrating the method of producing a sample for solid film evaluation.

FIG. 16E is a cross-sectional view illustrating the method of producing a sample for solid film evaluation.

FIG. 17A is a cross-sectional view illustrating a method of producing a sample for liquid film evaluation.

FIG. 17B is a cross-sectional view illustrating the method of producing a sample for liquid film evaluation.

FIG. 17C is a cross-sectional view illustrating the method of producing a sample for liquid film evaluation.

FIG. 17D is a cross-sectional view illustrating the method of producing a sample for liquid film evaluation.

FIG. 18 is a diagram illustrating an oxidation state of a copper film surface protected by a solid film.

FIG. 19 is a diagram illustrating an oxidation state of a copper film surface protected by a liquid film.

### DETAILED DESCRIPTION

Hereinafter, non-limiting example embodiments of the present disclosure will be described with reference to the accompanying drawings. In all the accompanying drawings, the same or corresponding members or components will be denoted by the same or corresponding reference numerals, and redundant descriptions thereof will be omitted.

### [Substrate Processing Method]

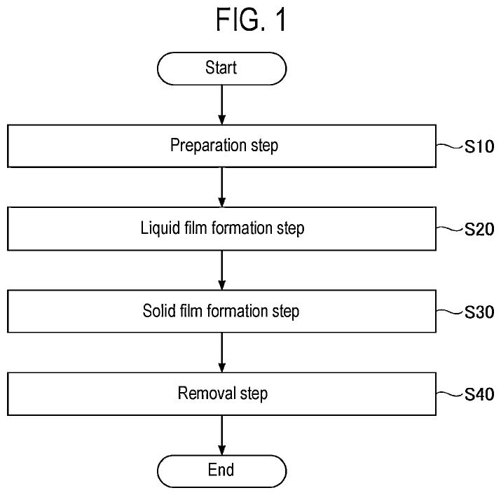

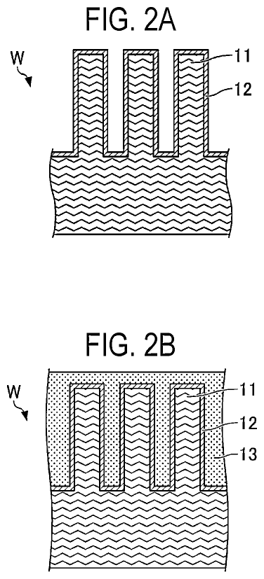

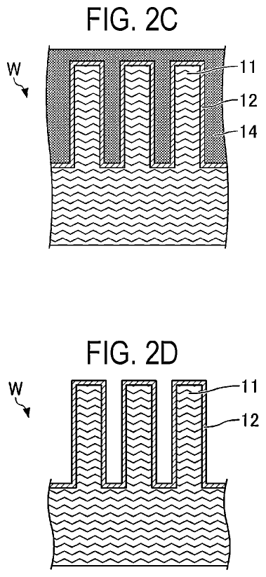

A substrate processing method according to an embodiment will be described with reference to FIGS. 1 and 2A to 2D. As illustrated in FIG. 1, the substrate processing method according to the embodiment includes a preparation step S10, a liquid film formation step S20, a solid film formation step S30, and a removal step S40.

The preparation step S10 includes preparing a substrate W having a surface with a pattern 11 covered with a metal film 12 (see FIG. 2A). The substrate W is, for example, a semiconductor wafer. The pattern 11 is, for example, a trench or hole. The metal film 12 is exposed on the surface of the substrate W. The metal film 12 may be, for example, a copper (Cu) film, an aluminum (Al) film, a cobalt (Co) film, a ruthenium (Ru) film, or a tantalum (Ta) film. The metal film 12 is formed by, for example, a chemical vapor deposition (CVD) method or a physical vapor deposition (PVD) method such as a sputtering method. However, the method of forming the metal film 12 is not limited to this. It may include removing a native oxide film on the surface of the substrate W only before forming the metal film 12, only after forming the metal film 12, or both before and after forming the metal film 12.

The liquid film formation step S20 is performed after the preparation step S10. It is desirable to perform the liquid film formation step S20 after the metal film 12 is formed without exposing the substrate W to an oxygen-containing atmosphere so that the metal film 12 exposed on the surface of the substrate W is not oxidized. The liquid film formation step S20 is carried out in an oxygen-free atmosphere such as a vacuum atmosphere or an inert gas atmosphere.

The liquid film formation step S20 includes forming an ionic liquid film (hereinafter referred to as “liquid film 13”) on a surface of the metal film 12 by supplying an ionic liquid to the surface of the substrate W at a first temperature (see FIG. 2B). The first temperature may be any temperature at which the ionic liquid may be applied in a liquid phase, for example, a temperature higher than the solidification point of the ionic liquid. The substrate W may be heated to a predetermined temperature during the supply of the ionic liquid. Heating the substrate W allows the ionic liquid to maintain a liquid phase on the surface of the substrate W, thereby facilitating the diffusion of the ionic liquid across the entire surface of the substrate W. The predetermined temperature may be the same as the first temperature. In addition, the substrate W may not be heated during the supply of the ionic liquid.

The ionic liquid contains an oxoacid structure having 6 or more carbon atoms. If the number of carbon atoms is 6 or more, the ionic liquid exhibits low viscosity at relatively low temperatures, which may allow the ionic liquid to be applied onto the substrate W at relatively low temperatures. 8 or more carbon atoms are preferred. In this case, it is easier to apply the ionic liquid onto the substrate W at low temperatures. If the ionic liquid contains the oxoacid structure, a solid film 14 to be described later may be easily removed. Details will be described later.

When using an ionic liquid to form a protective film in a Front End of Line (FEOL) step, it is desirable for the ionic liquid not to contain metal ions from the viewpoint of preventing the diffusion of a metal into a protection target film and others. If the ionic liquid contains metal ions, the metal ions contained in the ionic liquid may diffuse into the protection target film and others during heat treatment in the FEOL step, and it may deteriorate the characteristics of semiconductor devices.

The oxoacid structure may include at least one selected from the group of a cation and an anion. The oxoacid structure may be, for example, a carboxylic acid anion having 6 or more carbon atoms. A suitable carboxylic acid anion having 6 or more carbon atoms is a decanoic acid anion (C₉H₁₉COO—). If the ionic liquid contains the carboxylic acid anion having 6 or more carbon atoms, various species may be used as a cation. The cation may be, for example, a phosphoric acid cation or sulfuric acid cation.

A suitable specific example of the ionic liquid is trihexyltetradecylphosphonium decanoate (THTDP-DcO). If the ionic liquid is THTDP-DcO, the first temperature is desirably 50 degrees C. or higher and 200 degrees C. or lower, and more desirably 70 degrees C. or higher and 90 degrees C. or lower.

The solid film formation step S30 is performed after the liquid film formation step S20. The solid film formation step S30 is carried out in an oxygen-free atmosphere such as a vacuum atmosphere or an inert gas atmosphere. The solid film formation step S30 may be performed in the same chamber as the liquid film formation step S20, or may be performed in a different chamber from the liquid film formation step S20.

The solid film formation step S30 includes forming the solid film 14 by cooling the substrate W to a second temperature to solidify the liquid film 13 (see FIG. 2C). The solid film 14 has a higher barrier property against an oxidizing gas such as oxygen gas compared to the liquid film 13. Therefore, even if the substrate W having the solid film 14 formed thereon is exposed to an oxygen-containing atmosphere, the solid film 14 prevents the oxidizing gas from reaching the metal film 12. As a result, the oxidation of the metal film 12 is prevented. In this way, the solid film 14 functions as a protective film that protects the metal film 12 from the oxidizing gas. It is considered that the reason why the solid film 14 has a higher barrier property against the oxidizing gas compared to the liquid film 13 is because the liquid film 13 is crystallized when transitioning to a solid phase, resulting in a reduced pathway for oxygen diffusion. The second temperature is lower than the first temperature. The second temperature may be any temperature at which the liquid film 13 may be solidified, for example, a temperature equal to or lower than the solidification point of the ionic liquid. If the ionic liquid used in the liquid film formation step S20 is THTDP-DcO, the second temperature is desirably 20 degrees C. or more and 30 degrees C. or less, and more desirably 25 degrees C.

The removal step S40 is performed after the solid film formation step S30. There may be a step of exposing the substrate W to an air-containing atmosphere between the solid film formation step S30 and the removal step S40. The step of exposing the substrate W to the air-containing atmosphere may include, for example, transferring, by a transfer device, the substrate W in the air-containing atmosphere from a device where the solid film formation step S30 is performed to a device where the removal step S40 is performed. It is desirable to perform the removal step S40 immediately before the next step such as a film formation step. This may allow the solid film 14 to prevent the oxidation of the surface of the metal film 12 until just before the next step is performed.

The removal step S40 includes removing the solid film 14 by supplying a polar solvent to the substrate W (see FIG. 2D). The removal step S40 includes esterifying at least a part of the oxoacid structure contained in the solid film 14. If the ionic liquid contains the oxoacid structure, supplying the polar solvent to the solid film 14 causes at least a part of the oxoacid structure contained in the solid film 14 to undergo a condensation reaction with the polar solvent, leading to esterification. With this esterification of at least a part of the oxoacid structure, the solid film 14 is changed in polarity, exhibiting increased hydrophobicity and consequently, reduced adhesion to the metal film 12, which makes the solid film 14 easier to peel off from the surface of the metal film 12. In this way, if the ionic liquid contains the oxoacid structure, the solid film 14 formed by solidifying the liquid film 13 may be easily removed after being used as a protective film by simply supplying the polar solvent to the solid film 14 in the removal step S40. Further, since the solid film 14 may be removed in a solid phase without returning to a liquid phase, foreign matters such as particles adhered to the surface of the substrate W may be removed simultaneously with the solid film 14. The polar solvent may be, for example, an alcohol-based solvent such as methanol, ethanol, propanol, or isopropyl alcohol.

It is desirable to perform the removal step S40 in an inert gas atmosphere. This may prevent the oxidation of the metal film 12 exposed by the removal of the solid film 14. The inert gas atmosphere may be, for example, an argon atmosphere. If the polar solvent does not evaporate in a vacuum atmosphere, the removal step S40 may also be performed in a vacuum atmosphere. Further, the solid film 14 may be removed by ashing before supplying the polar solvent to the substrate W.

As described above, according to the substrate processing method of the embodiment, the ionic liquid containing the oxoacid structure having 6 or more carbon atoms is supplied to the surface of the substrate W at the first temperature to form the liquid film 13 on the surface of the metal film 12. Subsequently, the substrate W is cooled to the second temperature lower than the first temperature to solidify the liquid film 13, and thus the solid film 14 is formed. This enables the formation of a protective film that exhibits a high barrier property against an oxidizing gas and is easily removable.

### [Coating Device]

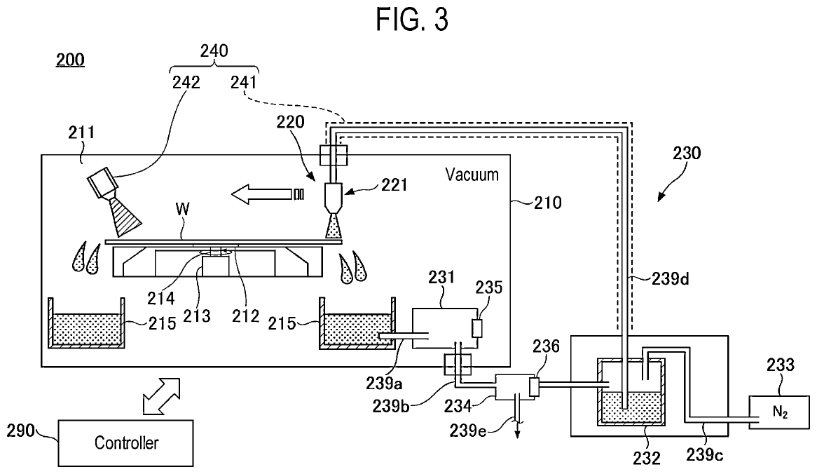

A vacuum slit coater 200, which is an example of a coating device, will be described with reference to FIG. 3. The vacuum slit coater 200 is capable of carrying out the liquid film formation step S20 and the solid film formation step S30 of the substrate processing method according to the embodiment.

The vacuum slit coater 200 includes a chamber 210, a liquid supplier 220, a liquid circulator 230, a heater 240, and a controller 290.

The chamber 210 forms a processing space 211 having a sealed structure for accommodating the substrate W therein. A stage 212 is installed inside the chamber 210. The stage 212 holds the substrate W in a substantially horizontal posture. The stage 212 is connected to an upper end of a rotating shaft 214, which is rotated by a drive mechanism 213, and thus, is rotatably configured. A liquid reservoir 215 with an open top side is installed below and around the stage 212. The liquid reservoir 215 receives and stores an ionic liquid that flows down or is shaken off from the substrate W. An interior of the chamber 210 is exhausted by an exhaust system (not illustrated) including a pressure control valve, a vacuum pump, and others.

The liquid supplier 220 includes a slit nozzle 221. The slit nozzle 221 is configured to horizontally move above the substrate W, thereby supplying an ionic liquid from the liquid circulator 230 to the surface of the substrate W placed on the stage 212.

The liquid circulator 230 collects the ionic liquid stored in the liquid reservoir 215 and supplies the ionic liquid to the slit nozzle 221. The liquid circulator 230 includes a compressor 231, an undiluted solution tank 232, a carrier gas source 233, a cleaner 234, and pH sensors 235 and 236.

The compressor 231 is connected to the liquid reservoir 215 via a pipe 239a to collect the ionic liquid stored in the liquid reservoir 215 and compress the ionic liquid to, for example, atmospheric pressure or higher. The compressor 231 is connected to the undiluted solution tank 232 via a pipe 239b to transport the compressed ionic liquid to the undiluted solution tank 232 through the pipe 239b. For example, a valve and a flow-rate controller (both not illustrated) are interposed in the pipe 239a. The ionic liquid is periodically transported from the compressor 231 to the undiluted solution tank 232, for example, by controlling the opening or closing of the valve.

The undiluted solution tank 232 stores the ionic liquid. One end of each of the pipes 239b to 239d is inserted into the undiluted solution tank 232. The other end of the pipe 239b is connected to the compressor 231, and the ionic liquid compressed by the compressor 231 is supplied to the undiluted solution tank 232 via the pipe 239b. The other end of the pipe 239c is connected to the carrier gas source 233, and a carrier gas such as nitrogen (N₂) gas is supplied from the carrier gas source 233 to the undiluted solution tank 232 via the pipe 239c. The other end of the pipe 239d is connected to the slit nozzle 221, and the ionic liquid inside the undiluted solution tank 232 is transported together with the carrier gas to the slit nozzle 221 via the pipe 239d. For example, a valve and a flow-rate controller (both not illustrated) are interposed in each of the pipes 239b to 239d.

The carrier gas source 233 is connected to the undiluted solution tank 232 via the pipe 239c to supply the carrier gas such as N₂ gas to the undiluted solution tank 232 through the pipe 239c.

The cleaner 234 is interposed in the pipe 239b. The cleaner 234 cleans the ionic liquid transported from the compressor 231. A drain pipe 239e is connected to the cleaner 234, and the ionic liquid having deteriorated properties is discharged through the drain pipe 239e. For example, the cleaner 234 controls whether to reuse or discharge the ionic liquid based on a detection value of the pH sensor 236. Further, for example, the cleaner 234 may control whether to reuse or discharge the ionic liquid based on a detection value of the pH sensor 235. Further, for example, the cleaner 234 may control whether to reuse or discharge the ionic liquid based on detection values of both the pH sensor 235 and the pH sensor 236.

The pH sensor 235 is provided at the compressor 231 to detect the hydrogen ion index (pH) of the ionic liquid in the compressor 231.

The pH sensor 236 is provided at the cleaner 234 to detect the hydrogen ion index (pH) of the ionic liquid in the cleaner 234.

The heater 240 includes a pipe heater 241 and a heating lamp 242. The pipe heater 241 is attached to the pipe 239d. The pipe heater 241 heats the ionic liquid flowing through the pipe 239d to the first temperature. This allows the liquefied ionic liquid to be applied to the substrate W on the stage 212. The heating lamp 242 is provided above the stage 212. The heating lamp 242 heats the substrate W placed on the stage 212 to a predetermined temperature by emitting light within the absorption wavelength range of the substrate W such as infrared light. The predetermined temperature may be, for example, the same as the first temperature. A plurality of heating lamps 242 may be provided.

The controller 290 processes computer-executable instructions for causing the vacuum slit coater 200 to execute the liquid film formation step S20 and the solid film formation step S30. The controller 290 may be configured to control each element of the vacuum slit coater 200 so as to execute the liquid film formation step S20 and the solid film formation step S30. The controller 290 includes, for example, a computer. The computer includes, for example, a CPU, a storage, and a communication interface.

An example of carrying out the liquid film formation step S20 and the solid film formation step S30 in the vacuum slit coater 200 as described above will be described.

First, the substrate W is loaded to the interior of the chamber 210 from a loading/unloading port (not illustrated), and then, the substrate W is placed on the stage 212. Subsequently, the substrate W on the stage 212 is heated to a predetermined temperature by the heating lamp 242. Subsequently, while the stage 212 is rotated by the drive mechanism 213, the ionic liquid is applied to the surface of the substrate W on the stage 212 using the slit nozzle 221. At this time, the ionic liquid is supplied to the slit nozzle 221 while being adjusted to the first temperature by the pipe heater 241. This allows the liquefied ionic liquid to be applied onto the substrate W on the stage 212, and leads to the diffusion of the ionic liquid across the entire surface of the substrate W. Further, by heating the substrate W with the heating lamp 242, the ionic liquid remains in a liquid phase on the surface of the substrate W, which facilitates the diffusion of the ionic liquid across the entire surface of the substrate W. In this way, the liquid film 13 may be formed across the entire surface of the substrate W. Subsequently, heating of the substrate W by the heating lamp 242 is stopped. This allows the substrate W to be cooled to the second temperature, solidifying the liquid film 13 and consequently, forming the solid film 14.

In addition, a case where the ionic liquid is circulated for reuse has been described in the above example, but this is not a limitation. For example, the ionic liquid may not be circulated. Further, a case where the substrate W on the stage 212 is cooled by stopping heating with the heating lamp 242 has been described in the above example, but this is not a limitation. For example, a cooling mechanism may be provided to cool the substrate W on the stage 212. The cooling mechanism may be either an air cooling type or a water cooling type.

### [Substrate Processing System]

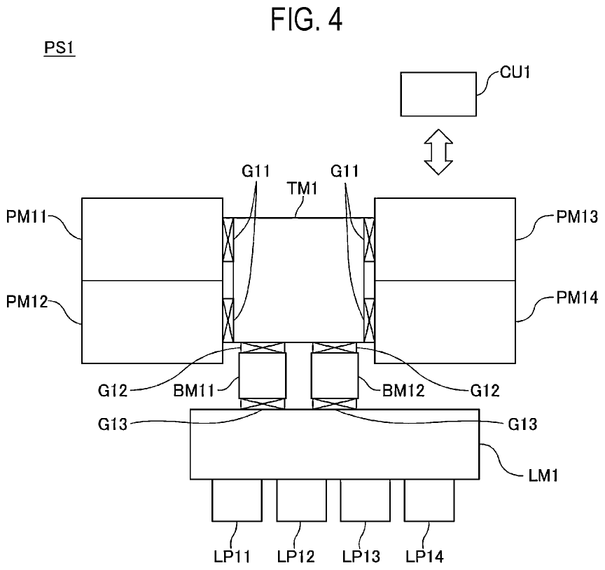

An example of a substrate processing system capable of carrying out the substrate processing method according to the embodiment will be described with reference to FIG. 4. As illustrated in FIG. 4, a substrate processing system PS1 is configured as an atmospheric apparatus.

The substrate processing system PS1 includes an atmospheric transfer module TM1, process modules PM11 to PM14, buffer modules BM11 and BM12, a loader module LM1, and others.

The atmospheric transfer module TM1 has a substantially rectangular shape in plan view. The atmospheric transfer module TM1 is connected at two opposite sides thereof to the process modules PM11 to PM14. The buffer modules BM11 and BM12 are connected to one side among the other two opposite sides of the atmospheric transfer module TM1. The atmospheric transfer module TM1 has a transfer chamber in an inert gas atmosphere, and a transfer robot (not illustrated) is arranged inside the atmospheric transfer module TM1. The transfer robot is configured to be pivotable, extendable/retractable, and vertically movable. The transfer robot transfers the substrate W based on an operation instruction output from a controller CU1 to be described later. For example, the transfer robot holds the substrate W with a fork arranged at a tip end thereof, and transfers the substrate W between the buffer modules BM11 and BM12 and the process modules PM11 to PM14. In addition, the fork is also called a pick or an end effector.

Each of the process modules PM11 to PM14 has a processing chamber and a stage (not illustrated) arranged therein. The atmospheric transfer module TM1 and the process modules PM11 to PM14 are partitioned by gate valves G11 that may be opened or closed.

The buffer modules BM11 and BM12 are arranged between the atmospheric transfer module TM1 and the loader module LM1. Each of the buffer modules BM11 and BM12 has a stage arranged therein. The substrate W is delivered between the atmospheric transfer module TM1 and the loader module LM1 via the buffer modules BM11 and BM12. The buffer modules BM11 and BM12 and the atmospheric transfer module TM1 are partitioned by gate valves G12 that may be opened or closed. The buffer modules BM11 and BM12 and the loader module LM1 are partitioned by gate valves G13 that may be opened or closed.

The loader module LM1 is arranged opposite to the atmospheric transfer module TM1. The loader module LM1 is, for example, an equipment front end module (EFEM). The loader module LM1 is an atmospheric transfer chamber that has a rectangular parallelepiped shape, includes a fan filter unit (FFU), and is maintained in an atmospheric pressure atmosphere. Two buffer modules BM11 and BM12 are connected to one longitudinal side of the loader module LM1. Load ports LP11 to LP14 are connected to the other longitudinal side of the loader module LM1. A container (not illustrated) for accommodating a plurality of (for example, 25) substrates W is placed on each of the load ports LP11 to LP14. The container is, for example, a front-opening unified pod (FOUP). A transfer robot (not illustrated) that transfers the substrate W is arranged inside the loader module LM1. The transfer robot is configured to be movable along the longitudinal direction of the loader module LM1, and is also configured to be pivotable, extendable/retractable, and vertically movable. The transfer robot transfers the substrate W based on an operation instruction output from the controller CU1. For example, the transfer robot holds the substrate W with a fork arranged at a tip end thereof, and transfers the substrate W between the load ports LP11 to LP14 and the buffer modules BM11 and BM12.

The substrate processing system PS1 is provided with the controller CU1. The controller CU1 may be, for example, a computer. The controller CU1 includes a central processing unit (CPU), a random access memory (RAM), a read only memory (ROM), an auxiliary storage device, and others. The CPU operates based on programs stored in the ROM or the auxiliary storage device to control each component of the substrate processing system PS1.

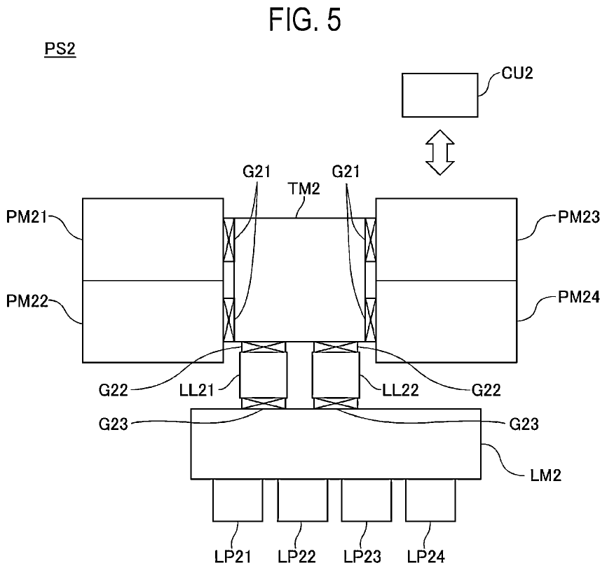

Another example of a substrate processing system capable of carrying out the substrate processing method according to the embodiment will be described with reference to FIG. 5. As illustrated in FIG. 5, a substrate processing system PS2 is configured as a vacuum apparatus.

The substrate processing system PS2 includes a vacuum transfer module TM2, process modules PM21 to PM24, load lock modules LL21 and LL22, a loader module LM2, and others.

The vacuum transfer module TM2 has a substantially rectangular shape in plan view. The vacuum transfer module TM2 is connected at two opposite sides thereof to the process modules PM21 to PM24. The load lock modules LL21 and LL22 are connected to one side among the other two opposite sides of the vacuum transfer module TM2. The vacuum transfer module TM2 has a vacuum chamber in a vacuum atmosphere, and a transfer robot (not illustrated) is arranged inside the vacuum transfer module TM2. The transfer robot is configured to be pivotable, extendable/retractable, and vertically movable. The transfer robot transfers the substrate W based on an operation instruction output from a controller CU2 to be described later. For example, the transfer robot holds the substrate W with a fork arranged at a tip end thereof, and transfers the substrate W between the load lock modules LL21 and LL22 and the process modules PM21 to PM24.

Each of the process modules PM21 to PM24 has a processing chamber and a stage (not illustrated) arranged therein. The process modules PM21 to PM24 include the vacuum slit coater 200 described above. The atmospheric transfer module TM2 and the process modules PM21 to PM24 are partitioned by gate valves G21 that may be opened or closed.

The load lock modules LL21 and LL22 are arranged between the vacuum transfer module TM2 and the loader module LM2. The load lock modules LL21 and LL22 have an internal pressure variable chamber, the interior of which is switchable between vacuum and atmospheric pressure. Each of the load lock modules LL21 and LL22 has a stage (not illustrated) arranged therein. When loading the substrate W from the loader module LM2 to the vacuum transfer module TM2, the load lock modules LL21 and LL22 maintain the interior thereof at atmospheric pressure to receive the substrate W from the loader module LM2, but lowers the internal pressure to load the substrate W into the vacuum transfer module TM2. When unloading the substrate W from the vacuum transfer module TM2 to the loader module LM2, the load lock modules LL21 and LL22 maintain the interior thereof at vacuum to receive the substrate W from the vacuum transfer module TM2, but raises the internal pressure up to atmospheric pressure to load the substrate W into the loader module LM2. The load lock modules LL21 and LL22 and the vacuum transfer module TM2 are partitioned by gate valves G22 that may be opened or closed. The load lock modules LL21 and LL22 and the loader module LM2 are partitioned by gate valves G23 that may be opened or closed.

The loader module LM2 is arranged opposite to the vacuum transfer module TM2. The loader module LM2 is, for example, an EFEM. The loader module LM2 is an atmospheric transfer chamber that has a rectangular parallelepiped shape, includes an FFU, and is maintained in an atmospheric pressure atmosphere. Two load lock modules LL21 and LL22 are connected to one longitudinal side of the loader module LM2. Load ports LP21 to LP24 are connected to the other longitudinal side of the loader module LM2. A container (not illustrated) for accommodating a plurality (for example, 25) of substrates W is placed on each of the load ports LP21 to LP24. The container is, for example, an FOUP. A transfer robot (not illustrated) that transfers the substrate W is arranged inside the loader module LM2. The transfer robot is configured to be movable along the longitudinal direction of the loader module LM2, and is also configured to be pivotable, extendable/retractable, and vertically movable. The transfer robot transfers the substrate W based on an operation instruction output from the controller CU2. For example, the transfer robot holds the substrate W with a fork arranged at a tip end thereof, and transfers the substrate W between the load ports LP21 to LP24 and the load lock modules LL21 and LL22.

The substrate processing system PS2 is provided with the controller CU2. The controller CU2 may be, for example, a computer. The controller CU2 includes a CPU, a RAM, a ROM, an auxiliary storage device, and others. The CPU operates based on programs stored in the ROM or the auxiliary storage device to control each component of the substrate processing system PS2.

### [Semiconductor Manufacturing Process Including Substrate Processing Method]

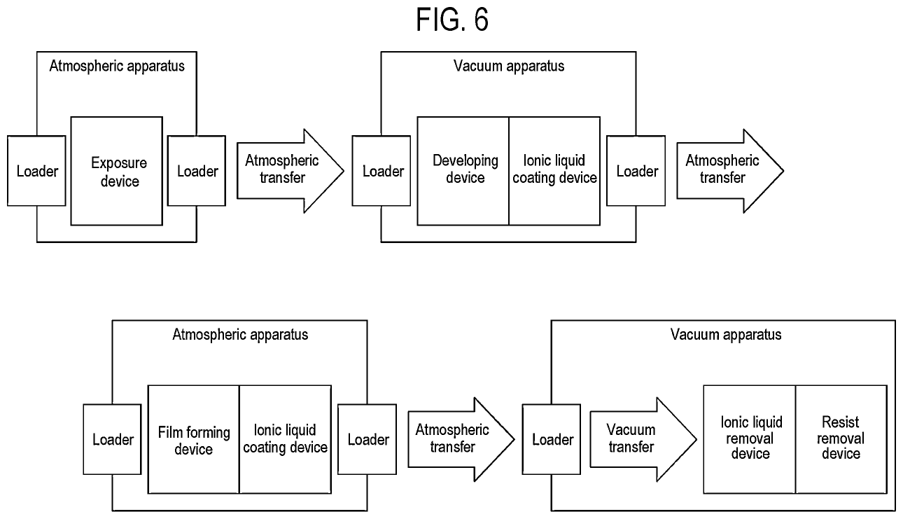

An example of a semiconductor manufacturing process to which the substrate processing method according to the embodiment may be applied will be described with reference to FIGS. 6 to 15.

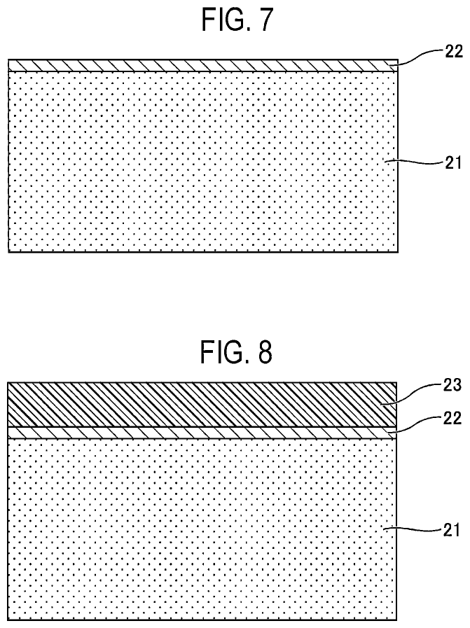

First, a copper film 22 is formed on a surface of a substrate 21 by electroless plating (see FIG. 7). The copper film has a thickness of 0.5 μm, for example. Subsequently, a resist film 23 is formed on the copper film 22 by coating (see FIG. 8).

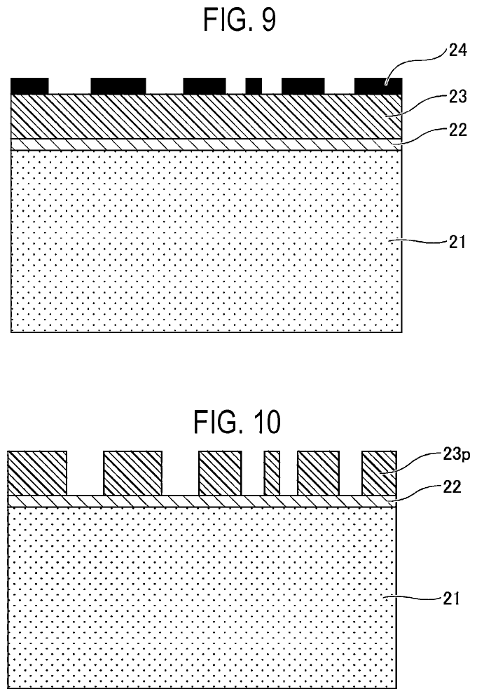

Subsequently, the substrate 21 having the resist film 23 formed thereon is transferred to an exposure device in the atmospheric apparatus via a loader, and the exposure device performs an exposure processing of exposing a part of the resist film 23 using a photomask 24 (see FIG. 9). The exposure device may be, for example, any of the process modules PM11 to PM14 in the substrate processing system PS1.

Subsequently, the substrate 21 subjected to the exposure processing is unloaded from the atmospheric apparatus via the loader, and is transferred into a vacuum apparatus via a loader by an atmospheric transfer mechanism. Subsequently, the substrate 21 transferred into the vacuum apparatus is transferred to a developing device in the vacuum apparatus, and the developing device forms a resist pattern 23p having an opening that exposes a part of the copper film 22 by developing the resist film 23 (see FIG. 10). The developing device may be, for example, any of the process modules PM21 to PM24 in the substrate processing system PS2.

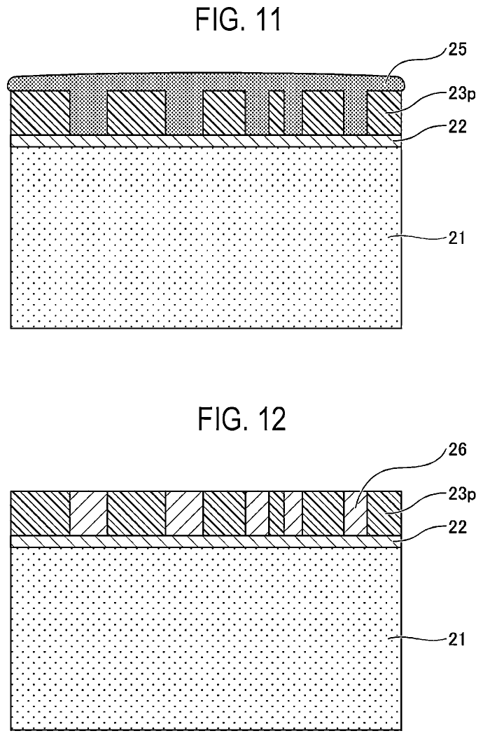

Subsequently, the substrate 21 is transferred from the developing device to an ionic liquid coating device, and the ionic liquid coating device applies an ionic liquid onto the resist pattern 23p, thereby forming an ionic liquid film 25 (see FIG. 11). When forming the ionic liquid film 25, it is desirable to apply the liquid film formation step S20 and the solid film formation step S30 of the substrate processing method according to the above-described embodiment. In this case, the ionic liquid film 25 functions as a protective film with a high barrier property against an oxidizing gas, thereby preventing the oxidizing gas from reaching the copper film 22. As a result, surface corrosion of the copper film 22 may be prevented. The ionic liquid coating device may be, for example, any of the process modules PM21 to PM24 in the substrate processing system PS2. In addition, the ionic liquid film 25 may be formed by the developing device.

Subsequently, the substrate 21 having the ionic liquid film 25 formed thereon is unloaded from the vacuum apparatus via the loader, and is transferred into the atmospheric apparatus through via loader by the atmospheric transfer mechanism. Subsequently, the substrate 21 transferred into the atmospheric apparatus is transferred to a film forming device in the atmospheric apparatus, and the film forming device forms a metal film 26 by performing a film formation processing on the substrate 21 (see FIG. 12). The film formation processing is, for example, plating. At this time, electrolytic plating using an ionic liquid may be performed since the ionic liquid has conductivity. Further, electroless plating may be performed. In addition, the ionic liquid film 25 applied onto the surface of the substrate 21 may be washed and removed (by replacement washing) from the film forming device before performing the film formation processing. When removing the ionic liquid film 25, it is desirable to apply the removal step S40 of the substrate processing method according to the above-described embodiment. In this case, the ionic liquid film 25 may be easily removed. Further, if the film formation processing is plating, the ionic liquid film 25 may be replaced (by replacement washing) with an ionic liquid in which a metal to be formed into a film is dissolved. The film forming device may be, for example, any of the process modules PM11 to PM14 in the substrate processing system PS1.

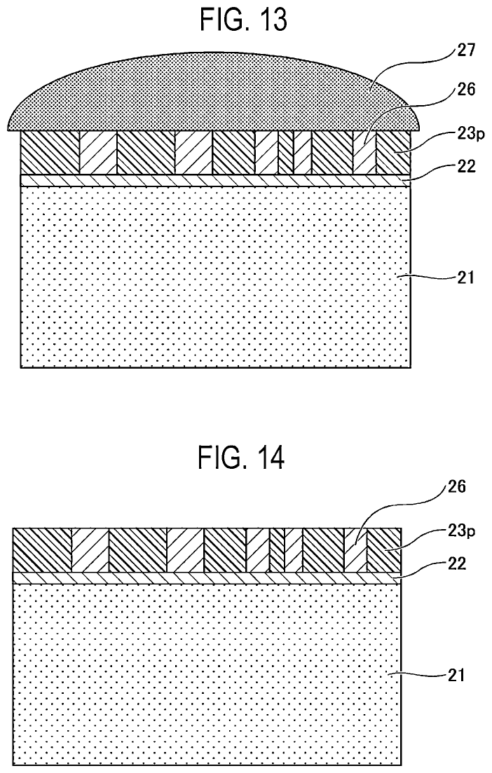

Subsequently, the substrate 21 is transferred from the film forming device to the ionic liquid coating device, and the ionic liquid coating device applies an ionic liquid onto the metal film 26, thereby forming an ionic liquid film 27 (see FIG. 13). When forming the ionic liquid film 27, it is desirable to apply the liquid film formation step S20 and the solid film formation step S30 of the substrate processing method according to the above-described embodiment. In this case, the ionic liquid film 27 functions as a protective film with a high barrier property against an oxidizing gas, thereby preventing the oxidizing gas from reaching the metal film 26. As a result, surface corrosion of the surface of the metal film 26 may be prevented. The ionic liquid coating device may be, for example, any of the process modules PM11 to PM14 in the substrate processing system PS1. In addition, the ionic liquid film 27 may be formed by the film forming device.

Subsequently, the substrate 21 having the ionic liquid film 27 formed thereon is unloaded from the atmospheric apparatus via the loader, and is transferred into the vacuum apparatus through via loader by the atmospheric transfer mechanism. Subsequently, the substrate 21 transferred into the vacuum apparatus is transferred to an ionic liquid removal device in the vacuum apparatus, and the ionic liquid removal device removes the ionic liquid film 27 (see FIG. 14). When removing the ionic liquid film 27, it is desirable to apply the removal step S40 of the substrate processing method according to the above-described embodiment. In this case, the ionic liquid film 27 may be easily removed. The ionic liquid removal device may be, for example, any of the process modules PM21 to PM24 in the substrate processing system PS2.

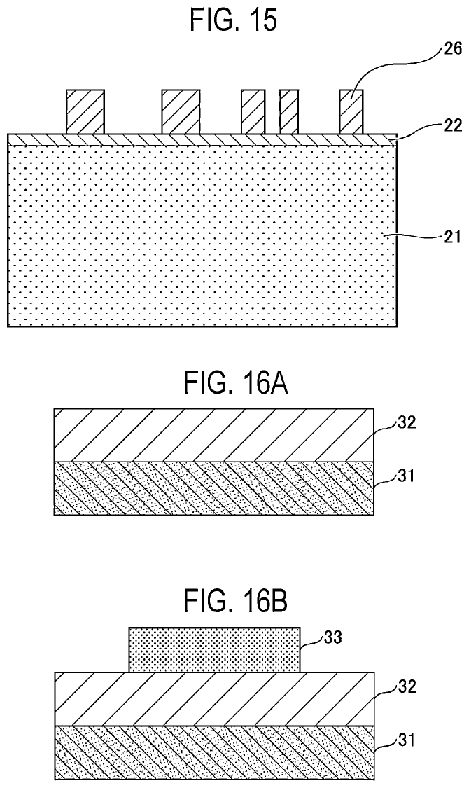

Subsequently, the substrate 21 is transferred from the ionic liquid removal device to a resist removal device, and the resist removal device removes the resist pattern 23p by ashing and others (see FIG. 15). The resist removal device may be, for example, any of the process modules PM21 to PM24 in the substrate processing system PS2. In addition, the resist pattern 23p may be removed by the ionic liquid removal device.

In addition, the loader of the atmospheric apparatus may be, for example, any of the load ports LP11 to LP14 in the substrate processing system PS1. The loader of the vacuum apparatus may be, for example, any of the load ports LP21 to LP24 in the substrate processing system PS2.

### [Evaluation Results]

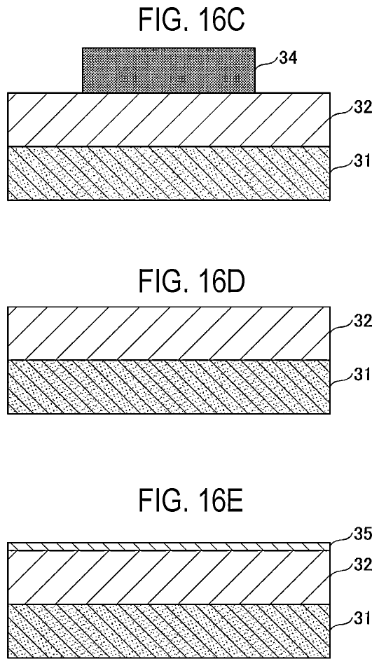

Referring to FIGS. 16A to 16E, 17A to 17D, 18 and 19, the oxidizing gas barrier properties of solid and liquid films made of THTDP-DcO, which is an example of an ionic liquid, were evaluated.

First, a method of producing a sample (hereinafter referred to as “sample for solid film evaluation”) for evaluating the oxidizing gas barrier property of a solid film made of THTDP-DcO will be described with reference to FIGS. 16A to 16E. FIGS. 16A to 16E are cross-sectional views illustrating a method of manufacturing a sample for solid film evaluation.

As illustrated in FIG. 16A, a copper film 32 was formed on a silicon substrate 31 by sputtering. Subsequently, as illustrated in FIG. 16B, THTDP-DcO was supplied onto a surface of the copper film 32 at 80 degrees C. to form a liquid film 33 on the surface of the copper film 32. Subsequently, as illustrated in FIG. 16C, the silicon substrate 31 was cooled to 25 degrees C. to solidify the liquid film 33, thus a solid film 34 is formed. Subsequently, the silicon substrate 31 was left in a dry air atmosphere with an oxygen concentration of about 20% for 24 hours. The higher the oxidizing gas barrier property of the solid film 34, the lower the degree of surface oxidation of the copper film 32 protected by the solid film 34 while the silicon substrate 31 is left in the dry air atmosphere. Subsequently, as illustrated in FIG. 16D, an alcohol-based solvent was supplied to the silicon substrate 31 to remove the solid film 34. Subsequently, as illustrated in FIG. 16E, a copper film 35 with a thickness of about 13 nm was formed on the copper film 32 by sputtering. The copper film 35 functions as a protective film to prevent the surface of the copper film 32, which is exposed after removing the solid film 34, from being oxidized before evaluation to be described later. Using the above method, a sample for solid film evaluation was produced. In addition, the formation of the copper film 32, the formation of the liquid film 33, the formation of the solid film 34, the removal of the solid film 34, and the formation of the copper film 35 were performed in an argon atmosphere with a dew point of −59 degrees C. and an oxygen concentration of 25 ppm.

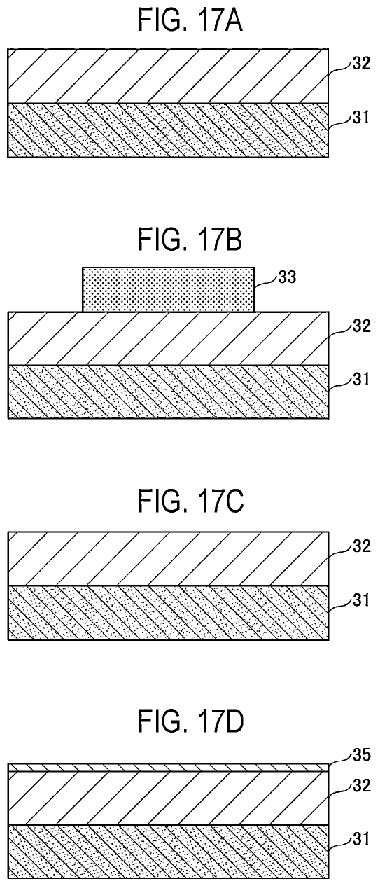

Subsequently, a method of producing a sample (hereinafter referred to as “sample for liquid film evaluation”) for evaluating the oxidizing gas barrier property of a liquid film made of THTDP-DcO will be described with reference to FIGS. 17A to 17D. FIGS. 17A to 17D are cross-sectional views illustrating a method of producing a sample for liquid film evaluation.

As illustrated in FIG. 17A, the copper film 32 was formed on the silicon substrate 31 by sputtering. Subsequently, as illustrated in FIG. 17B, THTDP-DcO was supplied onto a surface of the copper film 32 at 80 degrees C. to form the liquid film 33 on the surface of the copper film 32. Subsequently, while the liquid film 33 was maintained at 80 degrees C. to prevent the liquid film 33 from solidifying, the silicon substrate 31 was left in a dry air atmosphere with an oxygen concentration of about 20% for 24 hours. The higher the oxidizing gas barrier property of the liquid film 33, the lower the degree of surface oxidation of the copper film 32 protected by the liquid film 33 while the silicon substrate 31 is left in the dry air atmosphere. Subsequently, as illustrated in FIG. 17C, an alcohol-based solvent was supplied to the silicon substrate 31 to remove the liquid film 33. Subsequently, as illustrated in FIG. 17D, the copper film 35 with a thickness of about 22 nm was formed on the copper film 32 by sputtering. The copper film 35 functions as a protective film to prevent the surface of the copper film 32, which is exposed after removing the liquid film 33, from being oxidized before evaluation to be described later. Using the above method, a sample for liquid film evaluation was produced. In addition, the formation of the copper film 32, the formation of the liquid film 33, the removal of the liquid film 33, and the formation of the copper film 35 were performed in an argon atmosphere with a dew point of −59 degrees C. and an oxygen concentration of 25 ppm.

Subsequently, the atomic concentrations of oxygen atoms (O) and copper atoms (Cu) in the depth direction of the sample for solid film evaluation and the sample for liquid film evaluation were measured using X-ray photoelectron spectroscopy (XPS). The atomic concentrations were measured on the area of the copper film 32 protected by the solid film 34 and the liquid film 33, respectively, during the production of the sample for solid film evaluation and the sample for liquid film evaluation.

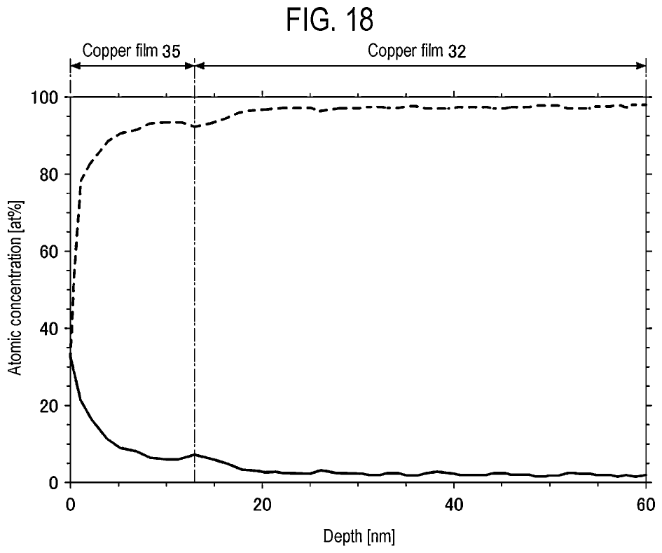

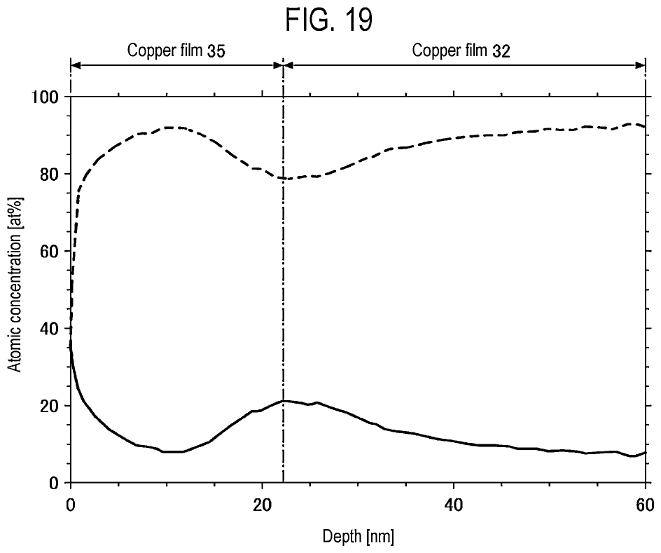

FIG. 18 is a diagram illustrating the oxidation state of the surface of the copper film 32 protected by the solid film 34, and indicates the atomic concentrations of oxygen atoms and copper atoms in the depth direction of the sample for solid film evaluation. FIG. 19 is a diagram illustrating the oxidation state of the surface of the copper film 32 protected by the liquid film 33, and indicates the atomic concentrations of oxygen atoms and copper atoms in the depth direction of the sample for liquid film evaluation. In FIGS. 18 and 19, the horizontal axis represents the depth [nm] from the surface of the copper film 35, and the vertical axis represents the atomic concentrations [at %] of oxygen atoms and copper atoms. In FIGS. 18 and 19, the solid line represents the atomic concentration of oxygen atoms, and the dashed line represents the atomic concentration of copper atoms.

As illustrated in FIGS. 18 and 19, it can be appreciated that the oxygen concentration on the surface of the copper film 32 in the sample for solid film evaluation is significantly lower than the oxygen concentration on the surface of the copper film 32 in the sample for liquid film evaluation. From these results, it was found that the barrier property against an oxidizing gas is significantly improved when THTDP-DcO is used in a solid phase.

The embodiments disclosed herein should be considered to be exemplary and not limitative in all respects. The above embodiments may be omitted, replaced, or changed in various forms without departing from the scope of the appended claims and their spirit.

In the above embodiment, a case of forming a protective film on a surface of a metal film, which is an example of a target film, has been described, but the present disclosure is not limited to this. For example, the target film may be any of various films aimed at preventing unintended surface deteriorations during semiconductor manufacturing steps. Examples of the various films may include conductive films such as polysilicon films, diffusion layers (p-type and n-type diffusion layers) on a semiconductor device substrate, and other films that are susceptible to surface oxidation by an oxidizing gas. By forming a protective film on the surface of the conductive films, diffusion layers, and others, it is possible to prevent surface oxidation of the conductive films, diffusion layers, and others. Examples of the various films may also include insulating films. The insulating films may be, for example, low-k films such as an SiOC film and a boron nitride (BN) film. The low-k films may deteriorate in terms of the k-value when the surface thereof is oxidized. By forming a protective film on the surface of the low-k films, deterioration of the k value may be prevented. The low-k films are used, for example, as interlayer insulating films.

This international application claims priority based on Japanese Patent Application No. 2022-036544 for which it filed on Mar. 9, 2022, and uses all the content of the said application for this international application.

### EXPLANATION OF REFERENCE NUMERALS

12: metal film, 13: liquid film, 14: solid film, W: substrate, S10: preparation step, S20: liquid film formation step, S30: solid film formation step, S40: removal step

1-10. (canceled)

11. A substrate processing method comprising:
preparing a substrate having a target film exposed on a surface of the substrate;
forming a liquid film on a surface of the target film by supplying an ionic liquid containing an oxoacid structure having 6 or more carbon atoms to the surface of the substrate at a first temperature;
forming a solid film by cooling the substrate to a second temperature lower than the first temperature to solidify the liquid film; and
removing the solid film by supplying a polar solvent to the substrate.

12. The substrate processing method of claim 11, wherein the second temperature is equal to or lower than a solidification point of the ionic liquid.

13. The substrate processing method of claim 11, wherein the removing the solid film includes esterifying at least a part of the oxoacid structure contained in the solid film.

14. The substrate processing method of claim 11, wherein the oxoacid structure includes a carboxylic acid anion.

15. The substrate processing method of claim 14, wherein the carboxylic acid anion is a decanoic acid anion.

16. The substrate processing method of claim 15, further comprising exposing the substrate to air between the forming the solid film and the removing the solid film.

17. The substrate processing method of claim 11, wherein the ionic liquid is trihexyltetradecylphosphoniumdecanoate.

18. The substrate processing method of claim 17, wherein the first temperature is 50 degrees C. or higher and 200 degrees C. or lower, and
wherein the second temperature is 20 degrees C. or higher and 30 degrees C. or lower.

19. The substrate processing method of claim 18, further comprising exposing the substrate to air between the forming the solid film and the removing the solid film.

20. The substrate processing method of claim 11, wherein the polar solvent is an alcohol-based solvent.

21. The substrate processing method of claim 11, further comprising exposing the substrate to air between the forming the solid film and the removing the solid film.

22. A substrate processing system comprising:
a first processing apparatus configured to perform a first processing on a substrate;
a second processing apparatus configured to perform a second processing on the substrate;
a third processing apparatus configured to perform a third processing on the substrate; and
a transfer device configured to transfer the substrate between the first processing apparatus and the second processing apparatus without exposing the substrate to an oxygen-containing atmosphere,
wherein the first processing includes: forming a target film on a surface of the substrate,
wherein the second processing includes: forming a liquid film on a surface of the target film by supplying an ionic liquid containing an oxoacid structure having 6 or more carbon atoms to the surface of the substrate at a first temperature; and forming a solid film by cooling the substrate to a second temperature lower than the first temperature to solidify the liquid film, and
wherein the third processing includes: removing the solid film by supplying a polar solvent to the substrate.
